(19) United States
(12) Patent Application Publication
(10) Pub. No.: US 2025/0293050 A1
(43) Pub. Date: Sep. 18, 2025

(54) WAFER PROCESSING METHOD AND WAFER PROCESSING APPARATUS

(71) Applicant: DISCO CORPORATION, Tokyo (JP)

(72) Inventor: Daisuke Hirouchi, Tokyo (JP)

(21) Appl. No.: 19/067,300

(22) Filed: Feb. 28, 2025

(30) Foreign Application Priority Data
Mar. 18, 2024 (JP) 2024-042653

(51) Int. Cl. H01L 21/56

(52) U.S. Cl. CPC H01L 21/56

(57) ABSTRACT

A wafer processing method includes: holding a first side of a wafer on a first holding surface of a first holder; supplying a liquid protection member to at least one of a second side of the wafer held by the first holder or a second holding surface of a second holder facing the first holder; bringing the first holding surface and the second holding surface relatively close to each other and coating the second side of the wafer with the protection member; curing the protection member; and before the curing, controlling a shape of at least one of the wafer held by the first holder or the protection member by applying an external force to at least one of the wafer held by the first holder or the supplied protection member.

### CROSS-REFERENCE TO RELATED APPLICATION(S)

The present application claims priority to and incorporates by reference the entire contents of Japanese Patent Application No. 2024-042653 filed in Japan on Mar. 18, 2024.

### BACKGROUND

The present disclosure relates to a wafer processing method and a wafer processing apparatus.

As a method for obtaining a flat wafer, there is known a method in which a protection member is formed by covering one side of a wafer with liquid resin and curing the resin, the opposite side to the protection member is ground, the protection member is peeled from the wafer, and a side to which the protection member has been attached is ground (see, for example, JP 2011-249652 A).

However, in the method of JP 2011-249652 A, since undulation or warpage of the wafer after grinding both sides varies depending on the attitude of the wafer in which the protection member has been formed, there is a disadvantage that a wafer having a desired shape cannot be obtained.

### SUMMARY

A wafer processing method according to one aspect of the present disclosure includes: holding a first side of a wafer on a first holding surface of a first holder; supplying a liquid protection member to at least one of a second side of the wafer held by the first holder or a second holding surface of a second holder facing the first holder; bringing the first holding surface and the second holding surface relatively close to each other and coating the second side of the wafer with the protection member; curing the protection member; and before the curing, controlling a shape of at least one of the wafer held by the first holder or the protection member by applying an external force to at least one of the wafer held by the first holder or the supplied protection member.

A wafer processing apparatus according to another aspect of the present disclosure includes: a first holder having a first holding surface that holds a first side of a wafer; a second holder having a second holding surface facing the first holder; a supplier configured to supply a liquid protection member to at least one of a second side of the wafer held by the first holder or the second holding surface; a movement mechanism configured to bring the first holder and the second holder relatively close to each other and covers the second side of the wafer with the protection member; a curing unit configured to cure the protection member; and a shape controller configured to apply an external force in a thickness direction of the wafer to the wafer or the protection member to control a shape of the wafer or the protection member, respectively, in the thickness direction.

### BRIEF DESCRIPTION OF THE DRAWINGS

FIG. 1 is a side cross-sectional view illustrating a configuration example of a wafer processing apparatus according to a first embodiment;

FIG. 2 is a side view illustrating an example of a wafer to be processed by a wafer processing method and the wafer processing apparatus according to the first embodiment;

FIG. 3 is a cross-sectional view illustrating a first holder of the wafer processing apparatus of FIG. 1;

FIG. 4 is a bottom view illustrating the first holder of the wafer processing apparatus of FIG. 1;

FIG. 5 is a flowchart illustrating a processing procedure of the wafer processing method according to the first embodiment;

FIG. 6 is a side cross-sectional view explaining a holding step in FIG. 5;

FIG. 7 is a side cross-sectional view explaining a shape control step in FIG. 5;

FIG. 8 is a side cross-sectional view explaining a coating step in FIG. 5;

FIG. 9 is a side cross-sectional view explaining a curing step in FIG. 5;

FIG. 10 is a side cross-sectional view explaining each step after the curing step in the wafer processing method in FIG. 5 is performed;

FIG. 11 is a cross-sectional view illustrating a first holder of a wafer processing apparatus according to a second embodiment;

FIG. 12 is a cross-sectional view illustrating a first holder of a wafer processing apparatus according to a third embodiment; and

FIG. 13 is a cross-sectional view illustrating a first holder of a wafer processing apparatus according to a fourth embodiment.

### DETAILED DESCRIPTION OF THE PREFERRED EMBODIMENTS

Modes for carrying out the present disclosure (embodiments) will be described in detail with reference to the drawings. The present invention is not limited by the content described in the following embodiments. In addition, the components described below include those that can be easily conceived of by those skilled in the art and those that are substantially the same. Furthermore, the configurations described below can be combined as appropriate. In addition, various omissions, substitutions, or modifications of the configurations can be made without departing from the gist of the present invention.

### First Embodiment

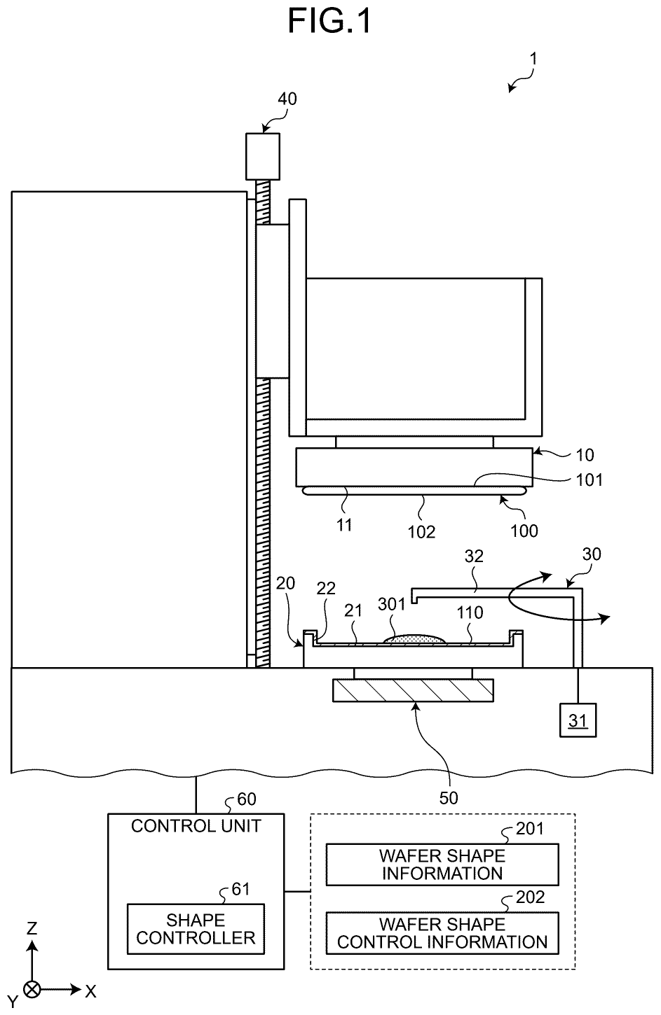

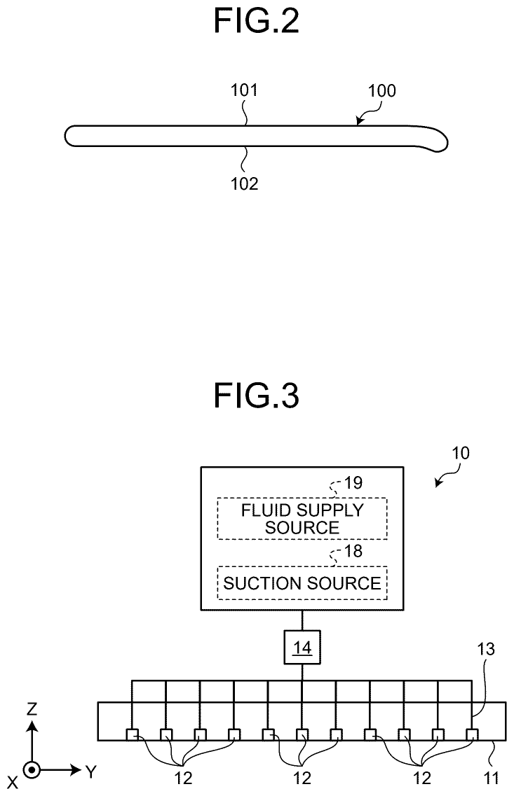

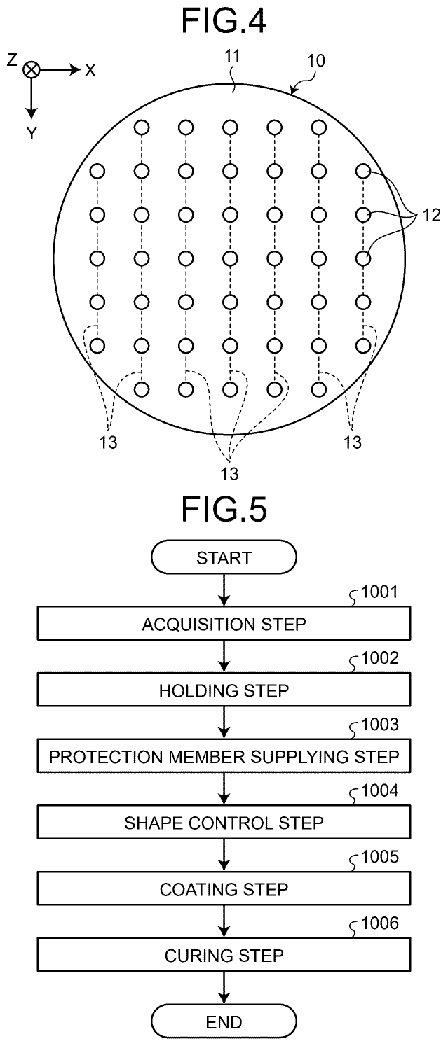

A wafer processing method and a wafer processing apparatus 1 according to a first embodiment of the present disclosure will be described with reference to the drawings. FIG. 1 is a side cross-sectional view illustrating a configuration example of the wafer processing apparatus 1 according to the first embodiment. FIG. 2 is a side view illustrating an example of a wafer 100 to be processed by the wafer processing method and the wafer processing apparatus 1 according to the first embodiment. FIG. 3 is a cross-sectional view illustrating a first holder 10 of the wafer processing apparatus 1 of FIG. 1. FIG. 4 is a bottom view illustrating the first holder 10 of the wafer processing apparatus 1 of FIG. 1.

The wafer processing method according to the first embodiment is an example of operation processing of the wafer processing apparatus 1 illustrated in FIG. 1 according to the first embodiment and is a method of processing the wafer 100 illustrated in FIG. 2. The wafer processing apparatus 1 illustrated in FIG. 1 according to the first embodiment is an example of an apparatus that performs the wafer processing method according to the first embodiment and is an apparatus that processes the wafer 100 illustrated in FIG. 2.

The wafer 100 to be processed by the wafer processing method and the wafer processing apparatus 1 according to the first embodiment is, for example, a disk-shaped semiconductor wafer or an optical device wafer obtained by using silicon, sapphire, gallium arsenide, or the like as a base material in the first embodiment. As illustrated in FIG. 2, the wafer 100 has a first side 101 and a second side 102 on the back side of the first side 101. The wafer 100 may include a plurality of division lines formed in a lattice shape on the first side 101 or the second side 102 that is flat, and a device may be formed in a region divided by the plurality of division lines. The wafer 100 may not include the division lines and may not be provided with a device. In the example of the first embodiment illustrated in FIG. 2, the wafer 100 is formed in a shape having warpage and undulation at an end with deformation toward the second side 102 in a region on the right side of the paper surface of FIG. 2 in a load-free state where no load except for the atmospheric pressure is applied.

As illustrated in FIG. 1, the wafer processing apparatus 1 according to the first embodiment includes the first holder 10, a second holder 20, a supplier 30, a movement mechanism 40, a curing unit 50, and a shape controller 61.

As illustrated in FIG. 1, the first holder 10 has a first holding surface 11 that holds the first side 101 of the wafer 100. The first holder 10 is formed in a disk shape, and the surface facing downward serves as the first holding surface 11 that sucks and holds the first side 101 of the wafer 100 from above. As illustrated in FIGS. 3 and 4, the first holder 10 has a plurality of openings 12 formed on the first holding surface 11. In the first embodiment, as illustrated in FIG. 4, the plurality of openings 12 formed on the first holding surface 11 is arrayed in a lattice pattern at equal intervals on the first holding surface 11 in a first direction parallel to the X-axis direction in FIG. 4 and a second direction orthogonal to the first direction and parallel to the Y-axis direction in FIG. 4. Although FIG. 3 illustrates such that ten openings 12 are formed in the X-axis direction, and FIG. 4 illustrates such that seven openings 12 are formed in the X-axis direction, actually, the same number of openings 12 are formed in the X-axis direction.

As illustrated in FIG. 3, in the first holder 10, one or a plurality of openings 12 and a plurality of communication paths 13 that connects a suction source 18 and a fluid supply source 19 are formed. First sides of the communication paths 13 communicate with the one or plurality of openings 12, and second sides thereof communicate with the suction source 18 and the fluid supply source 19 via a valve 14. In the first embodiment, as illustrated in FIGS. 3 and 4, the first sides of the communication paths 13 communicate with all openings 12 having the same positions in the first direction, and the number of the openings 12 is the same as the number of the openings arrayed in the first direction. However, the first sides of the communication paths 13 may communicate with all openings 12 having the same positions in the second direction, and the number of the openings 12 formed may be the same as the number of the openings arrayed in the second direction. Alternatively, one side of each of the communication paths 13 may be formed for one opening 12. Further alternatively, all the openings 12 may be grouped into any plural number of groups, one side of a communication path 13 may communicate with all openings 12 belonging to one group, and the same number of communication paths 13 may be formed as the number of the groups. As illustrated in FIG. 3, one valve 14 is provided for each communication path 13, and the same number as the number of communication paths 13, namely, a plurality of valves is provided. One suction source 18 and one fluid supply source 19 are provided.

A valve 14 can switch which of the suction source 18 or the fluid supply source 19 a second side of a communication path 13, provided with the valve 14, communicates with and is connected to, can also switch between an open state in which the communication path 13 provided with the valve 14 is opened and a closed state in which communication in the communication path 13 is blocked, and can control and adjust the opening amount in the communication path 13 provided with the valve 14 in the open state.

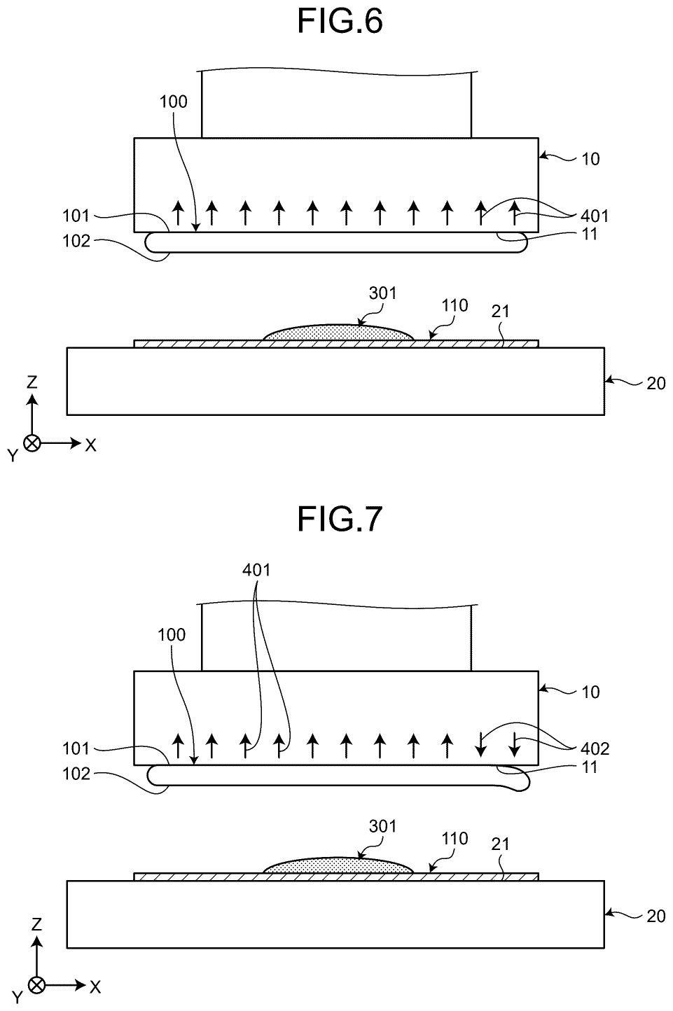

With a second side of the communication path 13 provided with the valve 14 switched to a state of being communicated with and connected to the suction source 18, the valve 14 introduces a negative pressure 401 (see FIG. 6 and others) from the suction source 18 onto the first holding surface 11 through an opening 12 communicating with and connected to the first side of the communication path 13 via the communication path 13 provided with the valve 14, thereby enabling suction. With the second side of the communication path 13 provided with the valve 14 switched to a state of being communicated with and connected to the fluid supply source 19, the valve 14 allows a fluid 402 (see FIG. 7 and others) to be supplied from the fluid supply source 19 onto the first holding surface 11 through the opening 12 communicating with and connected to the first side of the communication path 13 via the communication path 13 provided with the valve 14.

When switched to the open state in which the inside of the communication path 13 provided with the valve 14 is opened, the valve 14 introduces the negative pressure 401 from the suction source 18 or the fluid supply source 19 communicating with or connected to the second side of the communication path 13 provided with the valve 14 onto the first holding surface 11 through the opening 12 communicating with and connected to the first side of the communication path 13 via the communication path 13 provided with the valve 14, thereby enabling suction or allowing the fluid 402 to be supplied. When switched to the closed state in which the inside of the communication path 13 provided with the valve 14 is blocked, the valve 14 stops suction or supply of the fluid 402 through introduction of the negative pressure 401 from the suction source 18 or the fluid supply source 19 communicating with or connected to the second side of the communication path 13 provided with the valve 14 onto the first holding surface 11.

The valve 14 can control and adjust the magnitude (suction strength) of the negative pressure 401 introduced onto the first holding surface 11 or the flow rate of the fluid 402 to be supplied from the suction source 18 or the fluid supply source 19 communicating with and connected to the second side of the communication path 13 provided with the valve 14 onto the first holding surface 11 through the opening 12 communicating with and connected to the first side of the communication path 13 through the communication path 13 provided with the valve 14 by controlling and adjusting the opening amount in a state of being switched to the open state in which the communication path 13 provided with the valve is opened.

In the first embodiment, for example, a decompression pump or the like is used as the suction source 18. The fluid 402 supplied by the fluid supply source 19 preferably has little chemical influence on the wafer 100 and a liquid protection member 301, and in the first embodiment, for example, a gas such as pressurized air is used.

When all the valves 14 are switched such that the second sides of the communication paths 13 are connected to the suction source 18 and are in the open state, the first holding surface 11 of the first holder 10 functions as a suction holding surface that sucks and holds the first side 101 of the wafer 100 directed toward the first holding surface 11 by the negative pressure 401 introduced from the suction source 18 onto the first holding surface 11 through all the openings 12 via all the communication paths 13.

As illustrated in FIG. 1, the second holder 20 has a second holding surface 21 that faces the first holding surface 11 of the first holder 10 in the vertical direction (Z-axis direction in FIG. 1). When the first holding surface 11 of the first holder 10 holds the first side 101 of the wafer 100, the second holding surface 21 of the second holder 20 faces the second side 102 of the wafer 100 in the vertical direction. The second holder 20 is formed in a substantially disk shape and has a recess 22 slightly larger than the outer shape of the wafer 100 in plan view formed on a surface facing upward, a bottom surface of the recess 22 serving as the second holding surface 21.

The second holder 20 holds a sheet 110 supplied from a sheet supplier (not illustrated) from below by the second holding surface 21. In the first embodiment, the sheet 110 is formed slightly larger than the second holding surface 21 of the second holder 20 and is conveyed onto the second holding surface 21 of the second holder 20 by a sheet supplier (not illustrated). The second holder 20 receives supply of the liquid protection member 301 supplied from the supplier 30 onto the sheet 110 held by the second holding surface 21. In the first embodiment, the second holder 20 is provided with the curing unit 50 below in the vertical direction and is formed integrally with the curing unit 50. The second holder 20 receives the curing effect of the liquid protection member 301 supplied onto the sheet 110 from the curing unit 50 below via the sheet 110 held by the second holding surface 21.

In the first embodiment in which an ultraviolet curable resin is used as the liquid protection member 301, the second holder 20 and the sheet 110 are formed of a material that transmits at least a part of ultraviolet rays emitted from the curing unit 50 below. In this case, the second holder 20 is, for example, a glass table or the like formed of a material such as glass transparent to ultraviolet rays, and the sheet 110 is formed of a material such as polyolefin (PO) or polyethylene terephthalate (PET) transparent to ultraviolet rays.

In the present disclosure, the second holder 20 and the sheet 110 are not limited to the above. For example, in a case where a thermosetting resin is used as liquid protection member 301, the second holder 20 and the sheet 110 are formed of a material that suitably transfers heat from the curing unit 50 below. In addition, in a case where a mixture of an ultraviolet curable resin and a thermosetting resin is used as the liquid protection member 301, the second holder 20 and the sheet 110 are formed of a material that transmits at least a part of the ultraviolet rays emitted from the curing unit 50 below and suitably transmits the heat from the curing unit 50 below.

The supplier 30 supplies the liquid protection member 301 to at least one of the second side 102 of the wafer 100 held by the first holder 10 and the second holding surface 21 of the second holder 20. In the first embodiment, the supplier 30 supplies the liquid protection member 301 toward the second holding surface 21 of the second holder 20; however, the liquid protection member 301 may be supplied toward the second side 102 of the wafer 100 held by the first holder 10.

In the first embodiment, as illustrated in FIG. 1, the supplier 30 includes a supply source 31 of the liquid protection member 301 and a nozzle 32 that introduces the liquid protection member 301 from the supply source 31 toward the second holding surface 21 of the second holder 20. In the first embodiment, a liquid resin having a viscosity in a range of, for example, 0.5 Pas or more and 400 Pa's or less is suitably used as the liquid protection member 301 supplied by the supplier 30.

In the first embodiment, an ultraviolet curable resin is used as the liquid protection member 301 supplied by the supplier 30; however, a thermosetting resin may be used. In a case where an ultraviolet curable resin is used, the liquid protection member 301 supplied by the supplier 30 contains, for example, a curable resin component such as an ultraviolet curable resin and a binder polymer component such as an acrylic polymer. In a case where a thermosetting resin is used, the liquid protection member 301 supplied by the supplier 30 contains a thermosetting resin component such as an epoxy resin or a phenol resin and a binder polymer component such as an acrylic polymer. In addition, as the liquid protection member 301 supplied by the supplier 30, a mixture of an ultraviolet curable resin and a thermosetting resin may be used.

The nozzle 32 has a distal end side facing the second holding surface 21 of the second holder 20 and a proximal end side communicating with and connected to the supply source 31 that supplies the liquid protection member 301. By rotating a predetermined portion on the base end side as a fulcrum, the nozzle 32 can move the region to which the distal end side is directed between a supply region within the second holding surface 21 of the second holder 20 and a retraction region outside the second holding surface 21 of the second holder 20 and appropriately move the region to which the distal end side is directed within the second holding surface 21 of the second holder 20. The nozzle 32 can change and adjust the liquid protection member 301 to be supplied for each region on the second holding surface 21 of the second holder 20 by appropriately moving the region where the distal end side is directed within the second holding surface 21 of the second holder 20.

The movement mechanism 40 causes the first holder 10 and the second holder 20 to relatively approach each other and covers the second side 102 of the wafer 100 with the liquid protection member 301. In the first embodiment, the movement mechanism 40 is provided to the first holder 10, moves the first holder 10 relatively closer to the second holder 20 in the vertical direction, brings the second side 102 of the wafer 100 held on the first holding surface 11 of the first holder 10 closer to and into contact with the liquid protection member 301 supplied onto the second holding surface 21 of the second holder 20 by the supplier 30 to press the liquid protection member 301. In the first embodiment, the movement mechanism 40 is a known ball screw mechanism including a motor, a ball screw, and a guide. The movement mechanism 40 can control a relative movement speed of the first holder 10 relative to the second holder 20. The movement mechanism 40 can also control a pressing force for pressing the second side 102 of the wafer 100 held by the first holder 10 against the liquid protection member 301 on the second holding surface 21.

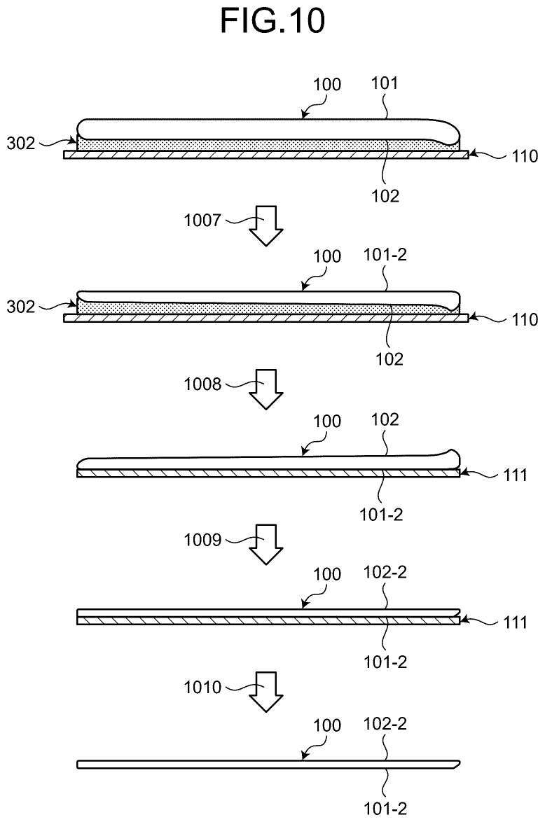

The curing unit 50 cures the liquid protection member 301 supplied to at least one of the second side 102 of the wafer 100 held by the first holder 10 or the second holding surface 21 of the second holder 20 to obtain a cured protection member 302 (see FIGS. 9 and 10). In the first embodiment, the curing unit 50 is provided below the second holding surface 21 of the second holder 20 and cures the liquid protection member 301 from the second holding surface 21 side of the second holder 20. However, for example, the curing unit 50 may be provided in the first holder 10 and cure the liquid protection member 301 from the second side 102 side of the wafer 100 held by the first holder 10.

In the first embodiment, since the ultraviolet curable resin is used as the liquid protection member 301, a plurality of ultraviolet emitters 51 (see FIG. 9) that emits ultraviolet rays 52 (see FIG. 9) is arrayed in a horizontal direction as the curing unit 50. The ultraviolet emitters 51 are, for example, ultraviolet LEDs. For example, in a case where a thermosetting resin is used as the liquid protection member 301, a heater may be used as the curing unit 50.

The shape controller 61 applies an external force in the thickness direction of the wafer 100 to the wafer 100 or the liquid protection member 301 to control the shape of the wafer 100 or the liquid protection member 301, respectively, in the thickness direction. Controlling the shape of the wafer 100 or the liquid protection member 301 in the thickness direction herein includes, in addition to controlling shape elements such as straightness (straightness), flatness (unevenness), roundness, or cylindricity (roundness and straightness) of the outer shape of the wafer 100 or the liquid protection member 301 such as each of the first side 101 and the second side 102, controlling attitude elements such as parallelism, perpendicularity, or inclination of the outer shape of the wafer 100 or the liquid protection member 301 such as between the first side 101 and the second side 102. The shape controller 61 applies an external force in the thickness direction of the wafer 100 to the wafer 100 held by the first holding surface 11 to control the shape of the wafer 100 in the thickness direction. However, an external force in the thickness direction of the wafer 100 may be applied to the liquid protection member 301.

In the first embodiment, the shape controller 61 implements a function of applying an external force in the thickness direction of the wafer 100 to the wafer 100 held on the first holding surface 11 by the plurality of openings 12, the plurality of communication paths 13, the plurality of valves 14, the suction source 18, and the fluid supply source 19 formed in the first holder 10 to control the shape of the wafer 100 in the thickness direction.

Specifically, the shape controller 61 switches valves 14 provided to communication paths 13 communicating with and connected to openings 12 formed in a region on the first holding surface 11 that correspond to a desired region of the wafer 100 held by the first holding surface 11 to a state in which second sides of the communication paths 13 communicate with and are connected to the suction source 18, whereby the negative pressure 401 is introduced from the suction source 18 onto the first holding surface 11 through the openings 12 via the communication paths 13, and the shape controller 61 can deform the wafer 100 held by the first holding surface 11 in a direction approaching the first holding surface 11 (upward in the vertical direction) in the desired region by applying an external force in the direction approaching the first holding surface 11 (upward in the vertical direction).

In addition, the shape controller 61 controls and adjusts the opening amount of the valves 14 to control and to adjust the magnitude of the negative pressure 401 (suction strength) introduced from the suction source 18 onto the first holding surface 11 through the openings 12, thereby controlling and adjusting the magnitude of the external force applied to the wafer 100 held by the first holding surface 11 in the direction approaching the first holding surface 11 (upward in the vertical direction) in the desired region to control and to adjust the deformation in the direction approaching the first holding surface 11 (upward in the vertical direction) to a desired magnitude.

Furthermore, the shape controller 61 switches the valves 14 provided to the communication paths 13 communicating with and connected to the openings 12 formed in the region on the first holding surface 11 that correspond to the desired region of the wafer 100 held by the first holding surface 11 to a state in which the second sides of the communication paths 13 communicate with and are connected to the fluid supply source 19, whereby the fluid 402 is supplied onto the first holding surface 11 through the openings 12 via the communication paths 13 from the fluid supply source 19, and the shape controller 61 can deform the wafer 100 held by the first holding surface 11 in a direction separated from the first holding surface 11 (downward in the vertical direction) in the desired region by applying an external force in the direction separated from the first holding surface 11 (downward in the vertical direction).

The shape controller 61 controls and adjusts the opening amount of the valve 14 to control and adjust the magnitude of the flow rate of the fluid 402 supplied from the fluid supply source 19 onto the first holding surface 11 through the opening 12, thereby controlling and adjusting the magnitude of the external force applied to the wafer 100 held by the first holding surface 11 in a direction (downward in the vertical direction) away from the first holding surface 11 in the desired region, and controlling and adjusting deformation in a direction (downward in the vertical direction) away from the first holding surface 11 to a desired magnitude.

The wafer processing apparatus 1 includes a control unit 60 that controls each component and each mechanism to cause the wafer processing apparatus 1 according to the first embodiment to perform each operation. The control unit 60 includes a shape controller 61.

The control unit 60 acquires and stores wafer shape information 201 which is information about the shape of the wafer 100 in a state of not being held by the first holder 10, namely, the shape of the wafer 100 in a load-free state where no load except for the atmospheric pressure is applied. The wafer shape information 201 is, for example, data representing the wafer 100 in a three-dimensional model in a substantially load-free state in which no load except for the atmospheric pressure is applied and, in the example of the first embodiment illustrated in FIG. 2, data reflecting the fact that the wafer 100 is formed in a shape having deformation toward the second side 102 with warpage and undulation at an end. In the control unit 60, the wafer shape information 201 may be input by an operator of the wafer processing apparatus 1 via an input unit (not illustrated) and stored.

Alternatively, the control unit 60 may measure the shape of the wafer 100 in the load-free state in which no load except for the atmospheric pressure is applied by a measurement unit (not illustrated) and acquire and store the wafer shape information 201.

In addition, the control unit 60 acquires and stores the wafer shape control information 202 which is information of processing by the shape controller 61 depending on the shape of the wafer 100 in various load-free states. The wafer shape control information 202 is obtained by associating, for each shape of the wafer 100 in various load-free states, information of processing by the shape controller 61 for controlling the wafer 100 to be closer to the shape of the wafer 100 in the load-free state when the wafer 100 is held by the first holder 10. Here, the information of the processing by the shape controller 61 is switching information of the connection destination, switching information of opening and closing, and information of the opening amount for each valve 14 in the first embodiment. In the control unit 60, the wafer shape control information 202 may be input by the operator of the wafer processing apparatus 1 via the input unit (not illustrated) and stored. In addition, the control unit 60 may acquire and store the wafer shape control information 202 by investigating, by an investigation unit (not illustrated), information of processing by the shape controller 61 for performing control so as to bring the shape of the wafer 100 to be close to a shape in various load-free states. Alternatively, the control unit 60 may acquire and store the wafer shape control information 202 from information stored in a desired server.

The control unit 60 is a computer including an arithmetic processing device having a microprocessor such as a central processing unit (CPU), a storage device having a memory such as a read only memory (ROM) or a random access memory (RAM), and an input and output interface device. The arithmetic processing device of the control unit 60 performs arithmetic processing in accordance with a computer program stored in the storage device and outputs a control signal for controlling the wafer processing apparatus 1 to each component and each mechanism of the wafer processing apparatus 1 via the input and output interface device.

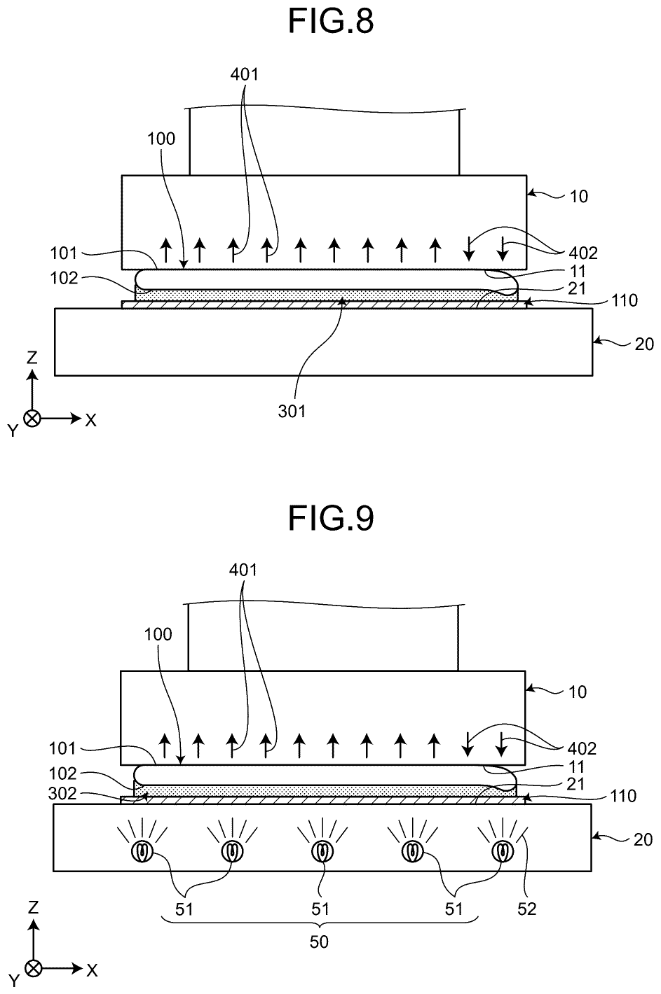

Next, the wafer processing method according to the first embodiment, which is an example of operation processing performed by the wafer processing apparatus 1 according to the first embodiment, will be described with reference to the drawings. FIG. 5 is a flowchart illustrating a processing procedure of the wafer processing method according to the first embodiment. FIG. 6 is a side cross-sectional view explaining a holding step 1002 in FIG. 5. FIG. 7 is a side cross-sectional view explaining a shape control step 1004 in FIG. 5. FIG. 8 is a side cross-sectional view explaining a coating step 1005 in FIG. 5. FIG. 9 is a side cross-sectional view explaining a curing step 1006 in FIG. 5. FIG. 10 is a side cross-sectional view explaining each step after the curing step 1006 in the wafer processing method in FIG. 5 is performed. Note that FIGS. 6 to 10 do not illustrate some components of the wafer processing apparatus 1 according to the first embodiment. As illustrated in FIG. 5, the wafer processing method according to the first embodiment includes an acquisition step 1001, the holding step 1002, a protection member supplying step 1003, the shape control step 1004, the coating step 1005, and the curing step 1006.

The acquisition step 1001 is a step of acquiring information about the shape of the wafer 100 in a state of not being held by the first holder 10. In the acquisition step 1001, for example, the control unit 60 measures the shape of the wafer 100 in the load-free state in which no load except for the atmospheric pressure is applied by a measurement unit (not illustrated) and acquires and stores the wafer shape information 201. Note that the acquisition step 1001 can be omitted in a case where information similar to the wafer shape information 201 for the wafer 100 to be processed by the wafer processing method according to the first embodiment is substantially acquired, such as that wafer shape information 201 for a wafer 100 in the same lot as the wafer 100 to be processed by the wafer processing method of the first embodiment has already been acquired. In a case where the acquisition step 1001 is performed without being omitted, it is performed before the holding step 1002 is performed.

The holding step 1002 is a step of holding the first side 101 of the wafer 100 by the first holding surface 11 of the first holder 10. In the holding step 1002, first, the control unit 60 controls a conveyance unit (not illustrated) to convey the wafer 100 toward the first holding surface 11 of the first holder 10 by the conveyance unit (not illustrated). In the holding step 1002, next, the control unit 60 controls the first holder 10 to switch all the valves 14 to connect the second sides of the communication paths 13 to the suction source 18 and to be in the open state and introduces the negative pressure 401 onto the first holding surface 11 from the suction source 18 through all the openings 12 via all the communication paths 13 to perform suction as illustrated in FIG. 6, whereby the first holder 10 sucks and holds, with the first holding surface 11, the first side 101 of the wafer 100 facing the first holding surface 11.

The protection member supplying step 1003 is a step of supplying the liquid protection member 301 to at least one of the second side 102 of the wafer 100 held by the first holder 10 or the second holding surface 21 of the second holder 20 facing the first holder 10.

In the protection member supplying step 1003, as illustrated in FIG. 6, in the first embodiment, first, the sheet supplier (not illustrated) supplies a sheet 110 formed slightly larger than the second holding surface 21 of the second holder 20 onto the second holding surface 21 of the second holder 20, and then, the supplier 30 supplies an appropriate amount of the liquid protection member 301 toward the sheet 110 disposed on the second holding surface 21 of the second holder 20. Therefore, the protection member supplying step may be performed before the holding step 1002 is performed or may be performed after the holding step 1002 is performed. Note that, in the protection member supplying step 1003, the liquid protection member 301 may be supplied toward the second side 102 of the wafer 100 held by the first holder 10 after the holding step 1002 is performed. The supply of the sheet 110 onto the second holding surface 21 of the second holder 20 may be omitted, and the liquid protection member 301 may be directly supplied onto the second holding surface 21 of the second holder 20.

The shape control step 1004 is a step of applying an external force to at least one of the wafer 100 held by the first holder 10 or the liquid protection member 301 supplied in the protection member supplying step 1003 to control the shape of at least one of the wafer 100 held by the first holder 10 or the liquid protection member 301, respectively, before the curing step 1006. In the first embodiment, in order to apply an external force in the thickness direction of the wafer 100 to the wafer 100 held by the first holding surface 11 and control the shape of the wafer 100 in the thickness direction, the shape control step 1004 is performed at least after the holding step 1002 is performed. However, in a case of applying an external force in the thickness direction of the wafer 100 to the liquid protection member 301 supplied in the protection member supplying step 1003 to control the shape of the wafer 100 in the thickness direction, the shape control step 1004 may be performed at least after the protection member supplying step 1003 is performed.

In the shape control step 1004, as illustrated in FIG. 7, in the first embodiment, the shape controller 61 performs at least one of supply or suction of the fluid 402 from the first holding surface 11 by the plurality of openings 12, the plurality of communication paths 13, the plurality of valves 14, the suction source 18, and the fluid supply source 19 formed in the first holder 10, thereby applying an external force in the thickness direction of the wafer 100 to the wafer 100 held by the first holding surface 11 to control the shape of the wafer 100 in the thickness direction. Note that, in the shape control step 1004, for example, similarly to the first embodiment in which at least one of supply or suction of the fluid 402 from the first holding surface 11 is performed, an external force in the thickness direction of the wafer 100 may be applied to the liquid protection member 301 by performing at least one of supply or suction of the fluid 402 from the second holding surface 21. Alternatively, in the shape control step 1004, an external force in the thickness direction of the wafer 100 may be applied to both the wafer 100 held by the first holding surface 11 and the liquid protection member 301 to control the shape of the wafer 100 in the thickness direction.

In the shape control step 1004, in the first embodiment, the shape controller 61 applies, to control the shape of the wafer 100 in the thickness direction, the external force in the thickness direction of the wafer 100 in such a direction that makes the shape of the wafer 100 close to that acquired in the acquisition step 1001 (the wafer shape information 201) or the wafer shape information 201 that can be regarded as information substantially similar to the shape of the wafer 100. Specifically, in the shape control step 1004, on the basis of the wafer shape information 201 and the wafer shape control information 202 acquired in advance or in the acquisition step 1001, the shape controller 61 acquires information of processing for performing control to make the shape of the wafer 100 close to that according to the wafer shape information 201 and performs switching of the connection destination, switching of opening and closing, and adjustment control of the opening amount for each valve 14 in accordance of the information of the processing, thereby applying an external force in the thickness direction of the wafer 100 to make the shape of the wafer 100 close to that according to the wafer shape information 201.

In the shape control step 1004, in the example of the first embodiment illustrated in FIG. 7, the shape controller 61 switches the valves 14 provided to the communication paths 13 communicating with and connected to the openings 12 formed in a region facing the region of the deformation to a state in which the second sides of the communication paths 13 communicates with and are connected to the fluid supply source 19 so as to make the shape of the wafer 100 close to that having deformation toward the second side 102 with warpage and undulation at the end in the region on the right side on the paper face in the load-free state, in which no load except for the atmospheric pressure is applied as illustrated in FIG. 2, and controls and adjusts the magnitude of the flow rate of the fluid 402 supplied from the fluid supply source 19 through the openings 12 via the communication paths 13 by controlling and adjusting the opening amount, thereby applying an external force in a direction away from the first holding surface 11 (downward in the vertical direction) is applied to the wafer 100 held by the first holding surface 11 in the region corresponding to the deformation and controlling and adjusting the magnitude of the external force to implement deformation similar to the deformation in the direction away from the first holding surface 11 (downward in the vertical direction).

The coating step 1005 is a step of bringing the first holding surface 11 and the second holding surface 21 relatively close to each other and covering the second side 102 of the wafer 100 with the liquid protection member 301. The coating step 1005 is performed after the holding step 1002, the protection member supplying step 1003, and the shape control step 1004 are performed. In the coating step 1005, in the first embodiment, the movement mechanism 40 moves the first holder 10 relatively closer to the second holder 20 in the vertical direction to bring the second side 102 of the wafer 100, which is held by the first holding surface 11 of the first holder 10 and the shape of which is controlled by the shape controller 61, closer to and into contact with and to press the liquid protection member 301 supplied by the supplier 30 onto the second holding surface 21 of the second holder 20, thereby deforming the liquid protection member 301 into a shape (attitude) corresponding to and close to the shape of the wafer 100 the shape of which is controlled by the shape controller 61 as illustrated in FIG. 8.

In the first embodiment, the shape of the wafer 100 is controlled in the shape control step 1004, and the shape of the liquid protection member 301 is deformed so as to follow the shape of the wafer 100 controlled in the shape control step 1004 in the coating step 1005. However, the shape of the liquid protection member 301 may be controlled in the shape control step 1004, and the shape of the wafer 100 may be deformed so as to follow the shape of the liquid protection member 301 controlled in the shape control step 1004 in the coating step 1005.

The curing step 1006 is a step of curing the liquid protection member 301 into the cured protection member 302. The curing step 1006 is performed after the coating step 1005 is performed. In the curing step 1006, in the first embodiment, as illustrated in FIG. 9, the curing unit 50 irradiates the liquid protection member 301 containing the ultraviolet curable resin with the ultraviolet ray 52 from the second holding surface 21 side of the second holder 20 by the plurality of ultraviolet emitters 51 such that the liquid protection member 301 is cured by the ultraviolet ray to obtain the cured protection member 302.

Note that, in the curing step 1006, the liquid protection member 301 containing an ultraviolet curable resin may be irradiated with ultraviolet rays from the first holding surface 11 side to be cured. Alternatively, in the curing step 1006, a liquid protection member 301 containing a thermosetting resin may be heated and cured from the second holding surface 21 side of second holder 20 or the first holding surface 11 side.

In the curing step 1006, by curing the liquid protection member 301 into the cured protection member 302, the second side 102 of the wafer 100 and the protection member 302 are bonded, and the protection member 302 and the sheet 110 are bonded, thereby integrating the wafer 100, the protection member 302, and the sheet 110. Since the curing step 1006 is performed after the coating step 1005 is performed, the wafer 100, the protection member 302, and the sheet 110 are integrated while maintaining the shapes of the wafer 100 held by the first holder 10 and of the liquid protection member 301 supplied in the protection member supplying step 1003, the shapes controlled through the steps up to the coating step 1005. That is, in the curing step 1006, the wafer 100, the protection member 302, and the sheet 110 are integrated while maintaining, for the wafer 100, a generally similar state to the substantial load-free state in which as least loads as possible other than the atmospheric pressure are applied.

As illustrated in FIG. 10, the wafer processing method according to the first embodiment may further include a first side flattening step 1007, a second side exposing step 1008, a second side flattening step 1009, and a wafer retrieval step 1010 after the curing step 1006.

The first side flattening step 1007 is a step of flattening the first side 101 of the wafer 100 opposite to the second side 102 to which the protection member 302 is bonded as illustrated in FIG. 10 after the curing step 1006 is performed. In the first side flattening step 1007, for example, the wafer 100 is held from the second side 102 side to which the protection member 302 is bonded, and a grinding wheel in which grinding stones are annularly arranged is pressed against the exposed first side 101 of the wafer 100 while rotating about the axis, whereby the first side 101 of the wafer 100 is ground and flattened to obtain a flat first side 101-2.

The second side exposing step 1008 is a step of exposing the second side 102 of the wafer 100 which the protection member 302 is bonded to and covering by removing the protection member 302 after the first side flattening step 1007 is performed as illustrated in FIG. 10. In the second side exposing step 1008, for example, the protection member 302 and the sheet 110 are peeled off from the second side 102 of the wafer 100, and a second sheet 111 is fixed to the first side 101-2 of the wafer 100. In this example, the second sheet 111 is, for example, an adhesive tape including a base material layer made of a synthetic resin and an adhesive layer laminated on one side of the base material layer and made of a synthetic resin having adhesiveness such as an adhesive agent.

The second side flattening step 1009 is a step of flattening the second side 102 of the wafer 100 exposed in the second side exposing step 1008 as illustrated in FIG. 10 after the second side exposing step 1008 is performed. In the second side flattening step 1009, for example, similarly to the first side flattening step 1007, the wafer 100 is held from the first side 101-2 side to which the second sheet 111 is fixed, and a grinding wheel in which grinding stones are annularly arranged is pressed against the exposed second side 102 of the wafer 100 while rotating about the axis, whereby the second side 102 of the wafer 100 is ground and flattened to obtain a flat second side 102-2.

The wafer retrieval step 1010 is a step of retrieving the wafer 100 having the flat first side 101-2 and the flat second side 102-2 as both sides after the second side flattening step 1009 is performed. In the wafer retrieval step 1010, for example, the second sheet 111 is peeled off from the first side 101-2 of the wafer 100 to retrieve the wafer 100 having the first side 101-2 and the second side 102-2 which are each flat.

The wafer processing method and the wafer processing apparatus 1 according to the first embodiment having the configuration as desired above controls the shape of the wafer 100 by applying the external force to the wafer 100 or the liquid protection member 301 in the shape control step 1004 before fixing the shapes of the wafer 100 and the liquid protection member 301 (cured protection member 302) by curing the liquid protection member 301 by the curing unit 50 to obtain the protection member 302 in the curing step 1006 and thus can fix the shape of the wafer 100 in a state of being controlled to a desired shape by the protection member 302 in the curing step 1006. Therefore, the wafer processing method and the wafer processing apparatus 1 according to the first embodiment can fix the shape of the wafer 100 in a state where residual stress causing undulation or warpage inside the wafer 100 is reduced or suppressed by controlling and fixing the shape of the wafer 100 to the shape of the wafer 100 in the load-free state where no load except for the atmospheric pressure is applied, thereby achieving the effects of reducing a change in undulation or warpage of the wafer 100 that occurs after any type of processing and more suitably providing the wafer 100 having a desired shape as compared with that in the related art.

Note that the wafer processing method and the wafer processing apparatus 1 according to the first embodiment can cure and fix the liquid protection member 301 in a state of having a residual stress that causes desired undulation or warpage inside the wafer 100 by modified to control and fix the shape of the wafer 100 to that in a load state that causes desired undulation or warpage, and therefore, the wafer processing method and the wafer processing apparatus 1 of the first embodiment can also be implemented by being modified to obtain a wafer 100 having a desired shape by performing desired processing such as cutting (dicing) processing, grinding processing, laser processing, or plasma processing on the wafer 100 after being fixed and releasing the fixture by the cured protection member 302 after the desired processing to release the residual stress such that the desired undulation or warpage is developed.

In the wafer processing method and the wafer processing apparatus 1 according to the first embodiment, in the shape control step 1004, the shape controller 61 performs at least one of supply or suction of the fluid 402 from the first holding surface 11 by the plurality of openings 12, the plurality of communication paths 13, the plurality of valves 14, the suction source 18, and the fluid supply source 19 formed in the first holder 10. As a result, the wafer processing method and the wafer processing apparatus 1 according to the first embodiment can suitably fix the shape of the wafer 100 in a state where the shape of the wafer 100 is controlled to a desired shape by applying an external force to the wafer 100 having higher rigidity than that of the liquid protection member 301. Therefore, it is possible to more suitably and more specifically obtain the wafer 100 having a desired shape as compared with that in the related art.

Furthermore, in the wafer processing method and the wafer processing apparatus 1 according to the first embodiment, in the shape control step 1004, the shape controller 61 may provide the second holding surface 21 with a plurality of openings 12, a plurality of communication paths 13, a plurality of valves 14, a suction source 18, and a fluid supply source 19 similar to those of the first holding surface 11, instead of performing at least one of supply or suction of the fluid 402 from the first holding surface 11, yet in a similar manner, and perform at least one of supply or suction of the fluid 402 from the second holding surface 21. In this case, the wafer processing method and the wafer processing apparatus 1 according to the first embodiment can fix the shape of the wafer 100 in a state where the shape of the wafer 100 is controlled to a desired shape by applying an external force to the liquid protection member 301 supplied onto the second holding surface 21. Therefore, it is possible to more suitably and more specifically obtain the wafer 100 having a desired shape as compared with that in the related art.

In the wafer processing method and the wafer processing apparatus 1 according to the first embodiment, the control unit 60 performs the acquisition step 1001 of acquiring information about the shape of the wafer 100 in a state where the wafer 100 is not held by the first holder 10, namely, in the load-free state where no load except for the atmospheric pressure is applied, and, in the shape control step 1004, the shape controller 61 applies an external force in such a direction that makes the shape of the wafer 100 close to that acquired in the acquisition step 1001. As a result, the wafer processing method and the wafer processing apparatus 1 according to the first embodiment can fix the shape of the wafer 100 in a state where residual stress causing undulation or warpage inside the wafer 100 is reduced or suppressed by fixing the shape of the wafer 100 in a state of being controlled to that in the load-free state where no load except for the atmospheric pressure is applied, thereby reducing a change in undulation or warpage of the wafer 100 that occurs after any type of processing and more suitably providing the wafer 100 having a desired shape as compared with that in the related art.

### Second Embodiment

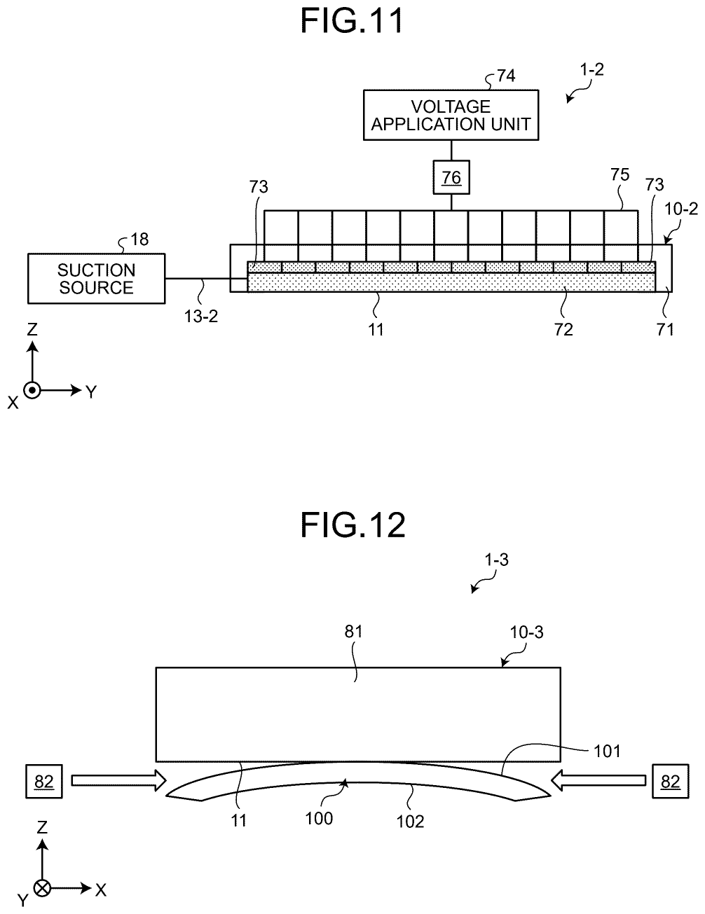

A wafer processing method and a wafer processing apparatus 1-2 according to a second embodiment of the present disclosure will be described with reference to the drawings. FIG. 11 is a cross-sectional view illustrating a first holder 10-2 of the wafer processing apparatus 1-2 according to the second embodiment. In FIG. 11, the same parts as those in the first embodiment are denoted by the same reference numerals, and description thereof is omitted.

The wafer processing method according to the second embodiment is an example of operation processing of the wafer processing apparatus 1-2 illustrated in FIG. 11 according to the second embodiment and is a method of processing the wafer 100 illustrated in FIG. 2. The wafer processing apparatus 1-2 illustrated in FIG. 11 according to the second embodiment is an example of an apparatus that performs the wafer processing method according to the second embodiment and is an apparatus that processes the wafer 100 illustrated in FIG. 2.

As illustrated in FIG. 11, the wafer processing apparatus 1-2 according to the second embodiment is modified so as to include a first holder 10-2 instead of the first holder 10 in the wafer processing apparatus 1 of the first embodiment, and the other configurations are similar to those of the first embodiment.

As illustrated in FIG. 11, the first holder 10-2 includes a disk-shaped frame 71 in which a recess is formed, a disk-shaped suction unit 72 fitted in the recess, a plurality of piezoelectric elements 73, a voltage application unit 74, a plurality of conduction paths 75 (conducting wires), and a plurality of switches 76. The suction unit 72 of the first holder 10-2 is formed of porous ceramic or the like having a large number of porous holes and is connected to a suction source 18 similar to that of the first embodiment via a communication path 13-2 formed in the frame 71. An exposed surface (lower surface) of the suction unit 72 of the first holder 10-2 facing downward constitutes a first holding surface 11 that sucks and holds the wafer 100 from above by a negative pressure introduced from the suction source 18 via the communication path 13-2.

The plurality of piezoelectric elements 73 is arrayed on a surface of the suction unit 72 opposite to the first holding surface 11. In the second embodiment, the plurality of piezoelectric elements 73 are each formed in a rectangular plate shape (square plate shape) having the same size and is arrayed in a lattice pattern on a surface of the suction unit 72 opposite to the first holding surface 11 in a first direction parallel to the X-axis direction in FIG. 11 and a second direction orthogonal to the first direction and parallel to the Y-axis direction in FIG. 11 without any gap therebetween.

As illustrated in FIG. 11, the first holder 10-2 is formed with the plurality of conduction paths 75 electrically connecting one or a plurality of piezoelectric elements 73 and the voltage application unit 74. A first side of a conduction path 75 is connected with one or a plurality of piezoelectric elements 73, and a second side is connected with the voltage application unit 74 via the switch 76. In the second embodiment, as illustrated in FIG. 11, the first sides of the conduction paths 75 are connected with all piezoelectric elements 73 having the same positions in the first direction, and the number of the conduction paths 75 is the same as the number of the piezoelectric elements 73 arrayed in the first direction. However, the first sides of the conduction paths 75 may be connected with all piezoelectric elements 73 having the same positions in the second direction, and the number of the conduction paths 75 formed may be the same as the number of the piezoelectric elements 73 arrayed in the second direction. Alternatively, one side of each of the conduction paths 75 may be formed for one piezoelectric element 73. Further alternatively, all the piezoelectric elements 73 may be grouped into any plural number of groups, one side of a conduction path 75 may communicate with all piezoelectric elements 73 belonging to one group, and the same number of conduction paths 75 may be formed as the number of the groups. As illustrated in FIG. 11, one switch 76 is provided for each conduction path 75, and the same number as the number of conduction paths 75, namely, a plurality of switches is provided. For example, a power supply, a battery, or the like is used as the voltage application unit 74, and one voltage application unit 74 is provided.

A switch 76 can switch between a conduction state in which the conduction path 75 provided with the switch 76 is closed for conduction and a blocked state in which the conduction path 75 is opened to block conduction and can control and adjust the voltage to be applied to a piezoelectric element 73 through the conduction path 75 provided with the switch 76 in the conduction state.

The switch 76 switches to the conduction state in which the conduction path 75 provided with the switch 76 is closed for conduction, thereby applying a voltage from the voltage application unit 74 connected with a second side of the conduction path 75 provided with the switch 76 to the piezoelectric element 73 connected with a first side of the conduction path 75 via the conduction path 75 provided with the switch 76 to cause the piezoelectric element 73 to expand or contract in the thickness direction of the wafer 100, thereby changing the position, in the thickness direction of the wafer 100, of the first holding surface 11 corresponding to the arrangement position of the piezoelectric element 73. The switch 76 switches to the blocked state in which the conduction path 75 provided with the switch 76 is opened to block conduction, thereby stopping application of a voltage to the piezoelectric element 73 from the voltage application unit 74 connected with the second side of the conduction path 75 provided with the switch 76 to stop expansion or contraction of the piezoelectric element 73 in the thickness direction of the wafer 100, thereby maintaining the position, in the thickness direction of the wafer 100, of the first holding surface 11 corresponding to the arrangement position of the piezoelectric element 73 at a fixed position.

The switch 76 can control and adjust the magnitude of expansion and contraction of the piezoelectric element 73 to which a voltage is applied from the voltage application unit 74 connected with the second side of the conduction path 75 provided with the switch 76 by controlling and adjusting the voltage applied to the piezoelectric element 73 through the conduction path 75 provided with the switch 76 in a state switched to the conduction state in which the conduction path 75 provided with the switch 76 is closed for conduction and thus can control and adjust the position of the first holding surface 11 in the thickness direction of the wafer 100, the position corresponding to the arrangement position of the piezoelectric element 73.

The wafer processing apparatus 1-2 according to the second embodiment is obtained by modifying the wafer processing apparatus 1 according to the first embodiment, in which the shape controller 61 applies an external force in the thickness direction of the wafer 100 to the wafer 100 held on the first holding surface 11 by the plurality of openings 12, the plurality of communication paths 13, the plurality of valves 14, the suction source 18, and the fluid supply source 19 formed in the first holder 10 to control the shape of the wafer 100 in the thickness direction, such that the shape of the wafer 100 in the thickness direction is controlled by applying an external force in the thickness direction of the wafer 100 to the wafer 100 held by the first holding surface 11 by generating a difference in the position of the first holding surface 11 in the thickness direction, in a region where the wafer 100 is held, by the plurality of piezoelectric elements 73 formed in the first holder 10-2, the voltage application unit 74, the plurality of conduction paths 75 (conducting wires), and the plurality of switches 76.

Specifically, the shape controller 61 switches the switch 76 provided in the conduction path 75 connected with the piezoelectric element 73 formed in a region on the first holding surface 11 corresponding to a desired region of the wafer 100 held by the first holding surface to the conduction state, thereby causing the piezoelectric element 73 to expand or contract by applying a voltage from the voltage application unit 74 to the piezoelectric element 73 via the conduction path 75 to change the position, in the thickness direction of the wafer 100, of the first holding surface 11 corresponding to the arrangement position of the piezoelectric element 73, thereby generating a difference in the position of the first holding surface 11 in the thickness direction in the region holding the wafer 100. The shape controller 61 can apply an external force in the thickness direction of the wafer 100 to the wafer 100 held by the first holding surface 11 in the desired region and deform the wafer 100 in the thickness direction by generating a difference in the position of the first holding surface 11 in the thickness direction in the region where the wafer 100 is held.

In addition, the shape controller 61 controls and adjusts the voltage applied to the piezoelectric element 73 through the conduction path 75 provided 76 with the switch 76 to control and to adjust the magnitude of the difference in the position in the thickness direction in the region of the first holding surface 11 where the wafer 100 is held, thereby controlling and adjusting the magnitude of the external force, in the thickness direction of the wafer 100, applied to the wafer 100 held by the first holding surface 11 in the desired region, thereby controlling and adjusting the deformation in the direction to a desired magnitude.

The wafer processing method according to the second embodiment are obtained by modifying the wafer processing method according to the first embodiment, in which the shape control step 1004 is performed by the shape controller 61 performing at least one of supply or suction of the fluid 402 from the first holding surface 11 by the plurality of openings 12, the plurality of communication paths 13, the plurality of valves 14, the suction source 18, and the fluid supply source 19 formed in the first holder 10 and applying an external force in the thickness direction of the wafer 100 to the wafer 100 held on the first holding surface 11 to control the shape of the wafer 100 in the thickness direction, such that the shape of the wafer 100 in the thickness direction is controlled by applying an external force in the thickness direction of the wafer 100 to the wafer 100 held by the first holding surface 11 by generating a difference in the position of the first holding surface 11 in the thickness direction, in a region where the wafer 100 is held, by the plurality of piezoelectric elements 73 formed in the first holder 10-2, the voltage application unit 74, the plurality of conduction paths 75 (conducting wires), and the plurality of switches 76.

The wafer processing method and the wafer processing apparatus 1-2 according to the second embodiment having the configuration as described above are obtained by modifying the wafer processing method and the wafer processing apparatus 1 according to the first embodiment, respectively, in which the shape control step 1004 is performed by the shape controller 61 applying an external force in the thickness direction of the wafer 100 to the wafer 100 held on the first holding surface 11 to control the shape of the wafer 100 in the thickness direction by the plurality of openings 12, the plurality of communication paths 13, the plurality of valves 14, the suction source 18, and the fluid supply source 19 formed in the first holder 10, such that the shape of the wafer 100 in the thickness direction is controlled by applying an external force in the thickness direction of the wafer 100 to the wafer 100 held by the first holding surface 11 by generating a difference in the position of the first holding surface 11 in the thickness direction, in a region where the wafer 100 is held, by the plurality of piezoelectric elements 73 formed in the first holder 10-2, the voltage application unit 74, the plurality of conduction paths 75 (conducting wires), and the plurality of switches 76. Therefore, the wafer processing method and the wafer processing apparatus 1-2 of the second embodiment have similar effects as those of the wafer processing method and the wafer processing apparatus 1 of the first embodiment. In addition, the wafer processing method and the wafer processing apparatus 1-2 according to the second embodiment can suitably fix the shape of the wafer 100 in a state where the shape of the wafer 100 is controlled to a desired shape by applying an external force to the wafer 100 having higher rigidity than that of the liquid protection member 301. Therefore, it is possible to more suitably and more specifically obtain the wafer 100 having a desired shape as compared with that in the related art.

### Third Embodiment

A wafer processing method and a wafer processing apparatus 1-3 according to a third embodiment of the present disclosure will be described with reference to the drawings. FIG. 12 is a cross-sectional view illustrating a first holder 10-3 of the wafer processing apparatus 1-3 according to the third embodiment. In FIG. 12, the same parts as those in the first embodiment and the second embodiment are denoted by the same reference numerals, and description thereof is omitted.

As illustrated in FIG. 12, the wafer processing apparatus 1-3 according to the third embodiment is modified so as to include a first holder 10-3 instead of the first holders 10 and 10-2 in the wafer processing apparatuses 1 and 1-2 of the first and second embodiments, and the other configurations are similar to those of the first and second embodiments.

As illustrated in FIG. 12, the first holder 10-3 includes a suction holding table 81 and an external force applier 82. The suction holding table 81 includes, for example, a disk-shaped frame in which a recess is formed and a disk-shaped suction unit fitted in the recess. The suction unit is formed of porous ceramic or the like having a large number of porous holes and is connected with a suction source (not illustrated) via a communication path (not illustrated) formed in the frame. An exposed surface (lower surface) of the suction unit facing downward constitutes a first holding surface 11 that sucks and holds the wafer 100 from above by a negative pressure introduced from the suction source (not illustrated) via the communication path (not illustrated).

As illustrated in FIG. 12, the external force applier 82 is provided on a radially outer side of the first holding surface 11 of the first holder 10-3 to face the first holding surface 11 radially inward. In the third embodiment, a plurality of external force appliers 82 is arrayed at equal intervals in the circumferential direction. In the third embodiment, for example, air blowing is performed to apply an external force to the outer peripheral side of the wafer 100 sucked and held by the first holding surface 11 of the first holder 10-3 by blowing air from the outer peripheral side of the first holding surface 11 of the first holder 10-3 to the first holding surface 11 radially inward.

The wafer processing method and the wafer processing apparatus 1-3 according to the third embodiment are obtained by modifying the method in the shape control step 1004 in which the shape controller 61 applies an external force in the thickness direction of the wafer 100 to the wafer 100 held on the first holding surface 11 to control the shape of the wafer 100 in the thickness direction in the wafer processing method and the wafer processing apparatuses 1 and 1-2 according to the first and second embodiment. In the wafer processing method and the wafer processing apparatus 1-3 according to the third embodiment, in the shape control step 1004, the shape controller 61 applies an external force in the thickness direction of the wafer 100 to the wafer 100 held on the first holding surface 11 by adjusting and controlling whether or not the external force is applied by the external force applier 82 and the pressure to be applied, thereby controlling the shape of the wafer 100 in the thickness direction.

The wafer processing method and the wafer processing apparatus 1-3 according to the third embodiment having the configuration as described above are obtained by modifying the wafer processing method and the wafer processing apparatuses 1 and 1-2 according to the first and second embodiments such that, in the shape control step 1004, the shape controller 61 applies an external force in the thickness direction of the wafer 100 to the wafer 100 held on the first holding surface 11 by adjusting and controlling whether or not the external force is applied by the external force applier 82 and the pressure to be applied, thereby controlling the shape of the wafer 100 in the thickness direction. Therefore, the wafer processing method and the wafer processing apparatus 1-3 of the third embodiment have similar effects to those of the wafer processing method and the wafer processing apparatuses 1 and 1-2 of the first and second embodiments. In addition, the wafer processing method and the wafer processing apparatus 1-3 according to the third embodiment can suitably fix the shape of the wafer 100 in a state where the shape of the wafer 100 is controlled to a desired shape by applying an external force to the wafer 100 having higher rigidity than that of the liquid protection member 301. Therefore, it is possible to more suitably and more specifically obtain the wafer 100 having a desired shape as compared with that in the related art.

### Fourth Embodiment

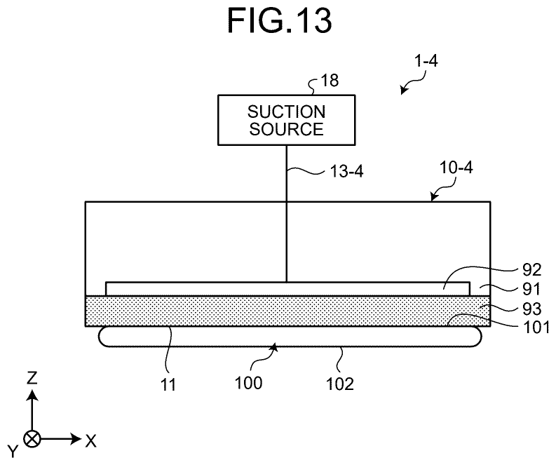

A wafer processing method and a wafer processing apparatus 1-4 according to a fourth embodiment of the present disclosure will be described with reference to the drawings. FIG. 13 is a cross-sectional view illustrating a first holder 10-4 of the wafer processing apparatus 1-4 according to the fourth embodiment. In FIG. 13, the same parts as those in the first, second, and third embodiments are denoted by the same reference numerals, and description thereof is omitted.

As illustrated in FIG. 13, the wafer processing apparatus 1-4 according to the fourth embodiment is modified so as to include a first holder 10-4 instead of the first holders 10, 10-2, and 10-3 in the wafer processing apparatuses 1, 1-2, and 1-3 of the first, second, and third embodiments, and the other configurations are similar to those in the first, second, and third embodiments.

As illustrated in FIG. 13, the first holder 10-4 includes a disk-shaped frame 91 in which a recess is formed, a disk-shaped suction unit 92 fitted in the recess, and an external force applying plate 93. The suction unit 92 of the first holder 10-4 is formed of porous ceramic or the like having a large number of porous holes and is connected with a suction source 18 similar to that of the first embodiment via a communication path 13-4 formed in the frame 91. A lower surface of the suction unit 92 of the first holder 10-4 sucks and holds the external force applying plate 93 from above by a negative pressure introduced from the suction source 18 via the communication path 13-2.

The external force applying plate 93 is formed in a plate shape, one surface thereof is sucked and held by the suction unit 92, and the other surface on the back side of the one surface constitutes a first holding surface 11 that sucks and holds the wafer 100 from above by a negative pressure introduced from the suction source 18 through the communication path 13-2 and a communication path 13 similar to that of the first embodiment (not illustrated) in the external force applying plate 93. As described above, in the first holder 10-4, the frame 91 and the suction unit 92 function as an external force applying plate holder that holds the external force applying plate 93 constituting the first holding surface 11 from above. In addition, the external force applying plate 93 is formed with a plurality of openings 12 and a plurality of communication paths 13 similar to those in the first embodiment and is provided with a plurality of valves 14, a suction source 18, and a fluid supply source 19 similar to those in the first embodiment.

That is, the wafer processing apparatus 1-4 according to the fourth embodiment is obtained by modifying the wafer processing apparatus 1 according to the first embodiment such that the plurality of openings 12 and the plurality of communication paths 13 are formed in the external force applying plate 93 and that the plurality of valves 14, the suction source 18, and the fluid supply source 19 are provided to the external force applying plate 93. Therefore, in the wafer processing method and the wafer processing apparatus 1-4 according to the fourth embodiment, similarly to the wafer processing method and the wafer processing apparatus 1 according to the first embodiment, in the shape control step 1004, the shape controller 61 applies an external force in the thickness direction of the wafer 100 to the wafer 100 held on the first holding surface 11 by the plurality of openings 12, the plurality of communication paths 13, the plurality of valves 14, the suction source 18, and the fluid supply source 19 formed in the first holder 10 to control the shape of the wafer 100 in the thickness direction.

In the wafer processing method and the wafer processing apparatus 1-4 according to the fourth embodiment having the configuration as described above, similarly to the wafer processing method and the wafer processing apparatus 1 according to the first embodiment, in the shape control step 1004, the shape controller 61 applies an external force in the thickness direction of the wafer 100 to the wafer 100 held on the first holding surface 11 by the plurality of openings 12, the plurality of communication paths 13, the plurality of valves 14, the suction source 18, and the fluid supply source 19 formed in the first holder 10 to control the shape of the wafer 100 in the thickness direction, and thus similar effects as those of the wafer processing method and the wafer processing apparatus 1 according to the first embodiment can be achieved. The wafer processing method and the wafer processing apparatus 1-4 according to the fourth embodiment are obtained by modifying the wafer processing method and the wafer processing apparatus 1 according to the first embodiment such that the plurality of openings 12 and the plurality of communication paths 13 are formed in the external force applying plate 93 and that the plurality of valves 14, the suction source 18, and the fluid supply source 19 are provided to the external force applying plate 93, thereby achieving the effect of the ease of operation with the external force applying plate newly provided, as compared to a conventional chuck table including a frame 91 and a suction unit 92.

According to the present disclosure, the shape of a wafer is controlled by applying an external force to the wafer or a liquid protection member in a shape control step before the shapes of the wafer and the liquid protection member are fixed by curing the liquid protection member in a curing step. Therefore, the shape of the wafer can be fixed in a state where the shape of the wafer is controlled to a desired shape by the protection member in the curing step. Therefore, it is possible to more suitably provide a wafer having a desired shape as compared with the related art.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A wafer processing method comprising:
holding a first side of a wafer on a first holding surface of a first holder;
supplying a liquid protection member to at least one of a second side of the wafer held by the first holder or a second holding surface of a second holder facing the first holder;
bringing the first holding surface and the second holding surface relatively close to each other and coating the second side of the wafer with the protection member;
curing the protection member; and
before the curing, controlling a shape of at least one of the wafer held by the first holder or the protection member by applying an external force to at least one of the wafer held by the first holder or the supplied protection member.

2. The wafer processing method according to claim 1, wherein the controlling includes performing at least one of supply of a fluid or suction from the first holding surface.

3. The wafer processing method according to claim 1, wherein the controlling includes performing at least one of supply of a fluid or suction from the second holding surface.

4. The wafer processing method according to claim 1, wherein the controlling includes generating a difference in a position of the first holding surface or the second holding surface in a thickness direction of the wafer in a region holding the wafer.

5. The wafer processing method according to claim 1, further comprising acquiring information about a shape of the wafer in a state where the wafer is not held by the first holder,
wherein the controlling includes applying the external force in such a direction that makes the shape of the wafer close to the acquired shape.

6. A wafer processing apparatus comprising:
a first holder having a first holding surface that holds a first side of a wafer;
a second holder having a second holding surface facing the first holder;
a supplier configured to supply a liquid protection member to at least one of a second side of the wafer held by the first holder or the second holding surface;
a movement mechanism configured to bring the first holder and the second holder relatively close to each other and covers the second side of the wafer with the protection member;
a curing unit configured to cure the protection member; and
a shape controller configured to apply an external force in a thickness direction of the wafer to the wafer or the protection member to control a shape of the wafer or the protection member, respectively, in the thickness direction.
